(19) United States
(12) Patent Application Publication
(10) Pub. No.: US 2026/0282292 A1
(43) Pub. Date: Sep. 17, 2026

(54) SYSTEM FOR COOLING A DATA CENTER

(71) Applicant: Edwin Kohl, Merzig (DE)

(72) Inventor: Edwin Kohl, Merzig (DE)

(21) Appl. No.: 19/224,256

(22) Filed: May 30, 2025

(30) Foreign Application Priority Data
Mar. 17, 2025 (DE) DE102025110217.1

(51) Int. Cl. H05K 7/20

(52) U.S. Cl. CPC H05K 7/208; H05K 7/20309; H05K 7/20318; H05K 7/20327; H05K 7/20363

(57) ABSTRACT

The present invention discloses a system for cooling a data center, in particular an artificial intelligence (AI) data center, comprising a plurality of computing modules (10) with semiconductor components which represent a heat source during operation, a cooling device for cooling the computing modules (10) by means of a coolant fluid circuit, the cooling device having an adsorption cooling device (50) with an evaporator (V), a condenser (K), and at least two adsorption/desorption elements (Ads/Des) forming the coolant fluid circuit, the condenser (K) having a thermal interface (51) for releasing heat to a reservoir (56), and a cold storage device (60) which is controllably thermally coupled via a first thermal interface (61) to the evaporator (V) of the adsorption cooling device (50) for buffer storage of a portion of the cold discharged by the evaporator (V).

### CROSS-REFERENCE TO RELATED APPLICATION(S)

This application claims a benefit of priority under 35 U.S.C. § 119(a) from German Patent Application No. DE 102025110217.1, filed on Mar. 17, 2025, entitled “SYSTEM FOR COOLING A DATA CENTER,” which is hereby expressly incorporated by reference herein for all purposes.

### TECHNICAL FIELD OF THE PRESENT DISCLOSURE

The present disclosure relates to a system for cooling a data center.

### BACKGROUND OF THE INVENTION

Due to the high and constantly increasing demand, the need for computing power in data centers has grown significantly. The increasing digitalization of the economy and society, the rapid development of cloud computing and, in recent years, the increasing use of artificial intelligence (AI) and machine learning play a major role in this. The development and application of AI and machine learning requires enormous computing resources, especially for the training of AI models. These technologies have a massive impact on data centers, as they require specialized hardware such as graphics processing units (GPUs) and tensor processing units (TPUs), which are much more powerful than conventional microprocessors (CPUs), but also consume more power and emit more heat.

Data centers generate an enormous amount of heat due to the high computing power and the operation of thousands of servers, which must be dissipated efficiently to protect the hardware from overheating and ensure stable operation. There are various methods of cooling data centers, such as air cooling, water cooling or immersion cooling, whereby servers or other IT components are immersed directly in a special, non-conductive coolant. The coolant efficiently dissipates the heat, reducing the amount of air or water cooling required.

The components in data centers, especially servers, processors and other electronic components, generate different temperatures during operation. The exact temperature depends on the type of component, the workload and the cooling methods. In general, data center components should not get too hot to avoid damage or performance degradation. Typical temperature ranges for processors (e.g., CPUs and GPUs) are between 30° C. and 50° C. in idle mode and 60° C. to 70° C. at full load. The higher temperature range is typical in AI data centers. Other electronic components such as memory or network components work at lower operating temperatures of around 30° C. to 50° C.

Data center cooling remains a major challenge, as it is crucial for both the performance and the energy efficiency and carbon footprint of a data center.

### SUMMARY OF THE INVENTION

According to the present disclosure, a system for cooling a data center comprising a plurality of computing modules with semiconductor devices is provided, which semiconductor devices represent a heat source during operation. The cooling system comprises a cooling device for cooling the computing modules by means of a coolant fluid circuit, the cooling device comprising an adsorption cooling device with an evaporator, a condenser and one or more adsorption/desorption elements for the coolant fluid, the condenser having a thermal interface for delivering heat to a thermal reservoir, and a cold storage device which is controllably thermally coupled to the adsorption cooling device for buffer storage of cold emitted by the adsorption cooling device.

The invention is based on the combination of one or more adsorption cooling devices, which are ideally suited for cooling in the temperature range from 55° C. to 70° C., with a device for storing or buffering cold, which can be used to handle power and/or temperature peaks. Keeping a cold reserve enables savings to be made in the design of the entire cooling system, whose maximum output can be reduced. Storing cold also makes it possible to react to fluctuations in the price of electricity and to reduce the cooling system's power consumption in the short term by using stored cold.

The cold storage device can be designed as a PCM (phase change material) cold storage device, which enables efficient cold storage in the specified temperature ranges. The thermal reservoir of the adsorption cooling device can be coupled with a second cold storage device.

Furthermore, the cold storage device can comprise a thermal building core storage reservoir, an underground cold storage device, a liquid storage tank and/or a local or district cooling network.

According to some embodiments, the ground cold storage reservoir, the thermal building core storage device, the liquid cold storage tank and/or the local or district cooling network can be thermally coupled with the thermal reservoir and/or the adsorption cooling device depending on the outside temperature. This means that, for example, a significant proportion of the cooling capacity can be provided by ambient cooling during winter operation, which can further reduce the energy consumption of the data center.

Furthermore, the adsorption/desorption elements of the adsorption cooling device can be thermally coupled with a solar thermal heating device for thermal support of the desorption process. This means that the energy consumption of the data center can also be further reduced through the use of solar energy.

In one embodiment, the solar thermal heating device can be configured to operate as a cooling source in a cooling mode depending on the outside temperature. In cooling mode, the solar thermal heating device can be thermally coupled with the adsorption element and/or the cooling reservoir.

According to some embodiments, the adsorption/desorption elements of the adsorption cooling device are thermally coupled with the computing modules of the data center, whereby the heat emitted by the computing modules is used to desorb the coolant fluid. The temperature range of powerful AI processors above 55° C. is ideal for desorption of the coolant, such as water.

According to some embodiments, the adsorption/desorption elements of the adsorption cooling device are thermally coupled to the computing modules of the data center by means of heat exchangers via a high-temperature cooling circuit, wherein the temperature of the heat exchange medium flowing back from the computing modules to the adsorption element is at least 500 C, preferably at least 550 C, and more preferably at least 600 C.

According to some embodiments, the adsorption and desorption elements of the adsorption cooling device can be thermally coupled to the computing modules of the data center in alternating cycles for continuous cooling operation.

The evaporator of the adsorption cooling device can be thermally coupled with other functional modules of the data center that have a lower operating temperature than the computing modules, such as memory or communication components.

The coolant fluid of the adsorption cooling device can, for example, be water.

The sorbent of the adsorption cooling device can be zeolite or silica gel.

The PCM material of the PCM storage unit can comprise water, salt solutions or kerosenes.

The invention also relates to a data center comprising a cooling system according to one of the preceding claims.

### BRIEF DESCRIPTION OF THE DRAWINGS

FIG. 1 shows a schematic representation of a first embodiment of a system for cooling a data center.

FIG. 2 shows a schematic representation of a second embodiment of a system for cooling a data center.

FIG. 2a shows a schematic representation of a variant of the system for cooling a data center shown in FIG. 2.

FIG. 2b shows a schematic representation of a further variant of the system for cooling a data center shown in FIG. 2.

FIG. 3 shows a schematic representation of a third embodiment of a system for cooling a data center.

FIG. 4 illustrates storing of cold in the system for cooling a data center as shown in FIG. 3.

FIG. 5 illustrates withdrawal of stored cold in the system for cooling a data center as shown in FIG. 3.

FIG. 6 shows a schematic representation of a fourth embodiment of a system for cooling a data center.

FIG. 7 illustrates a first partial cycle of an adsorption cooling device.

FIG. 8 illustrates a second partial cycle of an adsorption cooling device.

### DETAILED DESCRIPTION

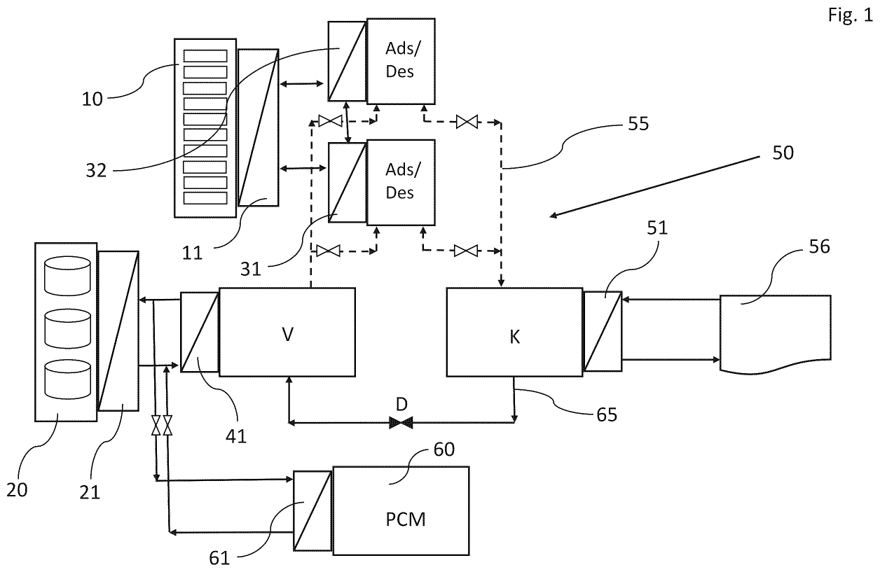

In the following, reference is made to exemplary embodiments of the disclosure, which are shown in the accompanying drawings. Wherever possible, the same reference signs are used in the drawings to refer to the same or similar entities. Furthermore, the features and technical effects explained in connection with a particular embodiment, e.g. that shown in FIG. 1, also apply to all other embodiments, unless otherwise described. Unless otherwise specified, features and effects of different embodiments can be combined appropriately.

### Adsorption Cooling Devices

Adsorption cooling devices are thermally driven chillers. They use a solid sorbent, such as activated carbon, zeolite or silica gel, to compress a refrigerant using a sorptive process. The sorbent is located in an apparatus that acts as an adsorber and desorber alternately.

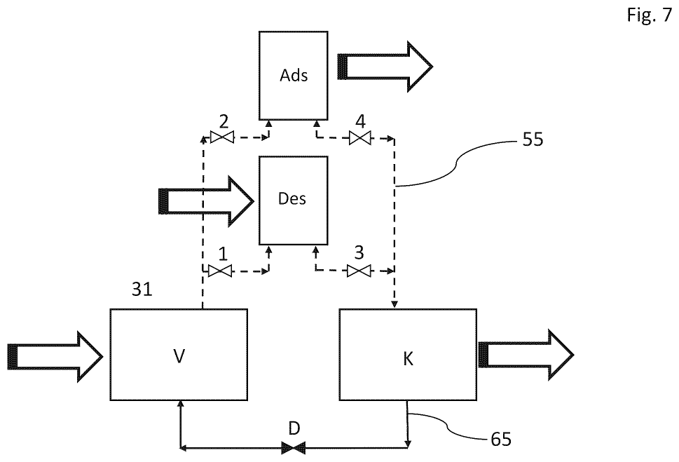

An adsorption cooling device, such as that known e.g. from WO 2017/174235, is shown schematically in FIG. 7 and essentially consists of an evaporator V, an adsorber Ads, a desorber Des, a condenser K and a throttle D. Since two adsorbers/desorbers are provided, the cooling process can be operated alternately and thus continuously, i.e. without interruption.

The working medium, for example water, is adsorbed on a solid adsorbent in the adsorber device Ads. The resulting negative pressure causes the working medium to change to a gaseous state in the evaporator V. The evaporator V absorbs heat (arrow) from the environment and can therefore be used for cooling.

In parallel, the working medium is expelled from the desorber Des by supplying external heat. The working medium then enters the condenser K in a gaseous state and is liquefied there. In the process, it releases the heat (arrow) absorbed at evaporator V together with the heat supplied to desorber Des at condenser K. The working medium then returns to the evaporator V in liquid form via a return flow. This closes the working circuit of the adsorption cooling device. The device therefore works as a heat pump, with no fans or other moving parts required, which means that the adsorption cooling device can work very efficiently and can be operated with low maintenance.

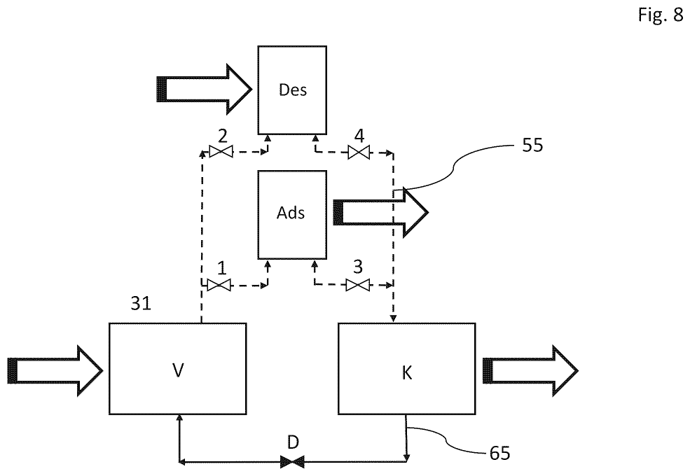

Once the adsorber Ads is saturated with the working medium, the system switches to the second part of the working cycle, which is illustrated in FIG. 8.

Valve 2 is closed and valve 4 is opened, whereby the previous adsorber Ads becomes the desorber Des. At the same time, valve 1 is opened and valve 3 is closed so that the previous desorber becomes the adsorber Ads.

The working circuit formed between evaporator V, adsorber/desorber and condenser K contains section 55 (dashed), in which the working medium is present in gaseous form, and section 65, in which the working medium is present in liquid form.

The working medium within the liquid half-cycle 55 can be mixed with a suitable functional medium that can perform different tasks, such as reducing the vapor pressure of the working medium during the evaporation process in the evaporator V.

### PCM (Phase Change Material) Thermal Storage

A cold storage device based on phase change materials (PCM), also known as latent cold storage, uses the ability of materials to switch between a solid and liquid state when the temperature changes, for example, and to store or release heat through this phase change.

PCM cold accumulators use materials that change from one state to another-for example from solid to liquid—at a temperature within the appropriate temperature range. During this phase change, a large amount of heat energy is absorbed or released without significant change of the temperature of the material. This form of thermal energy released during a phase change is known as latent heat. When ice melts or water freezes, for example, the temperature at atmospheric pressure is fairly constant at 00 C, and boiling water has a constant temperature of 1000 C.

The main advantage of this technology is that it stores latent heat—i.e. the heat that is absorbed or released during a phase change (for example from solid to liquid) without directly changing the temperature of the material.

A commonly used material is kerosene wax, which melts at a temperature of around 20° C. to 30° C. When used in a latent heat storage system, it can absorb and store excess heat as it transitions from a solid to a liquid state. When the temperature drops, it releases this stored heat as it transitions from liquid to solid again.

The advantages of a PCM cold accumulator include:
Energy efficiency: PCM cold accumulators offer high energy efficiency because they can store a large amount of thermal energy without significantly changing their temperature. This means that they can provide constant cooling when required without the need for constant coolant replenishment or additional energy consumption.
Space efficiency: This type of cooling requires less space and has less equipment complexity than conventional systems with evaporators or large chillers, as the stored energy is stored compactly in the material itself in the form of latent heat.
Continuous cooling: As PCM cold accumulators can store heat efficiently over longer periods of time, they offer the possibility of uniform cooling without fluctuations, which is particularly advantageous in areas such as data centers, medical facilities or the food industry.
Sustainability: The use of phase change materials for cooling can reduce the environmental impact, as fewer mechanical cooling units are required and fewer refrigerants (which are often harmful to the climate) are used.

Latent cold storage systems thus offer an effective and sustainable solution for cooling in various applications. Their ability to efficiently store and release large amounts of thermal energy makes them a promising technology.

### Examples of the Invention

FIG. 1 schematically shows a first embodiment of a system for cooling a data center.

The mode of operation of the adsorption cooling device 50 corresponds in principle to the adsorption cooling device described in FIGS. 7 and 8.

The adsorption cooling device 50 according to FIG. 1 has an evaporator V, two adsorbers/desorbers Ads/Des, a condenser K and a choke D. Since two adsorbers/desorbers are provided, the cooling process again can be operated quasi-continuously, i.e. without interruption.

The two adsorbers/desorbers Ads/Des are connected via heat exchangers 31, 32 in a cooling circuit to the heat exchanger 11 of a computing module 10, which contains, for example, the high-performance processors (e.g., CPUs, TPUs or GPUs) of an AI data center, which emit large amounts of heat under full load. This is preferably a high-temperature cooling circuit in which the heat emitted by the processors is used to desorb the working medium (preferably water) in the circuit of the adsorption cooling device 50. The provided fluid temperature of the high-temperature cooling circuit 31, 32, 11 is, for example, at least 600C, and the return temperature is, for example, at least 550 C. Thus, on the one hand, the processors of the computing module 10 can be kept at a constant temperature and, on the other hand, the desorption of the working medium of the adsorption cooling device 50 can be carried out efficiently.

The evaporator V, which emits cold, is connected via a cooling circuit comprising the heat exchangers or thermal interfaces 21, 41 to a further functional module 20 of the data center, which further functional module 20 contains electronic components such as memory elements or network components that have a lower operating temperature (for example 300 C to 450 C or also 180 C to 230 C) than the processors of the module 10. The cooling circuit 21, 41 is therefore a low-temperature cooling circuit. The return temperature from the module 20 is 250 C, for example, and the flow temperature to the module is, for example 200 C or 150 C.

The cooling circuit 21, 41 has a valve-controlled branch to the heat exchanger 61 of a cold storage device 60, which in the embodiment shown in FIG. 1 is designed as a PCM cold storage device or latent cold storage device, which—as explained above—stores the cold by means of a phase transition of a suitable cold storage material such as water, salt solutions or kerosenes.

The working medium condenses in the condenser K, releasing heat which is transferred to a cold reservoir 56.

The working circuit formed between evaporator V, adsorber/desorber and condenser K contains a section 55 (dashed) in which the working medium is present in gaseous form and a section 65, in which the working medium is present in liquid form.

The working medium within the liquid half-cycle 55 can be mixed with a suitable functional medium that can perform different tasks, such as reducing the vapor pressure of the working medium during the evaporation process in the evaporator V.

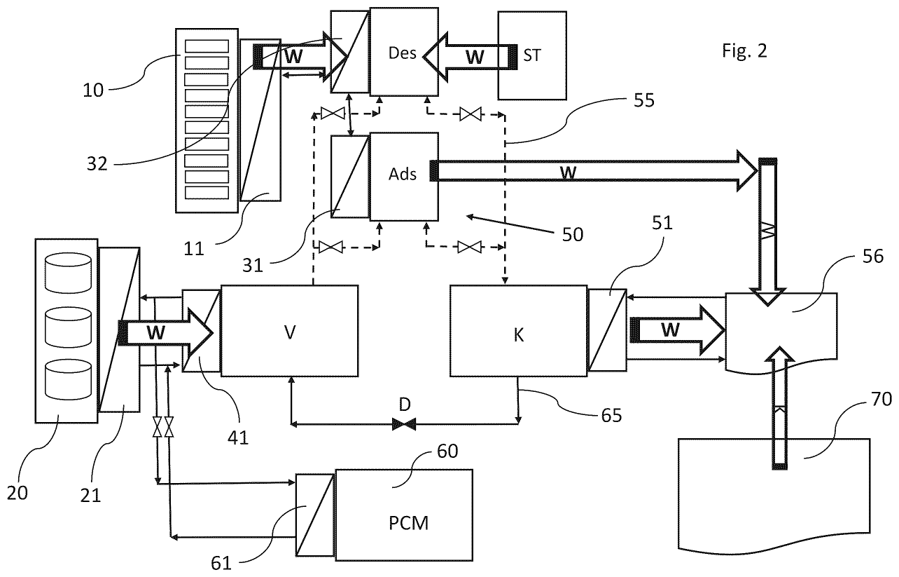

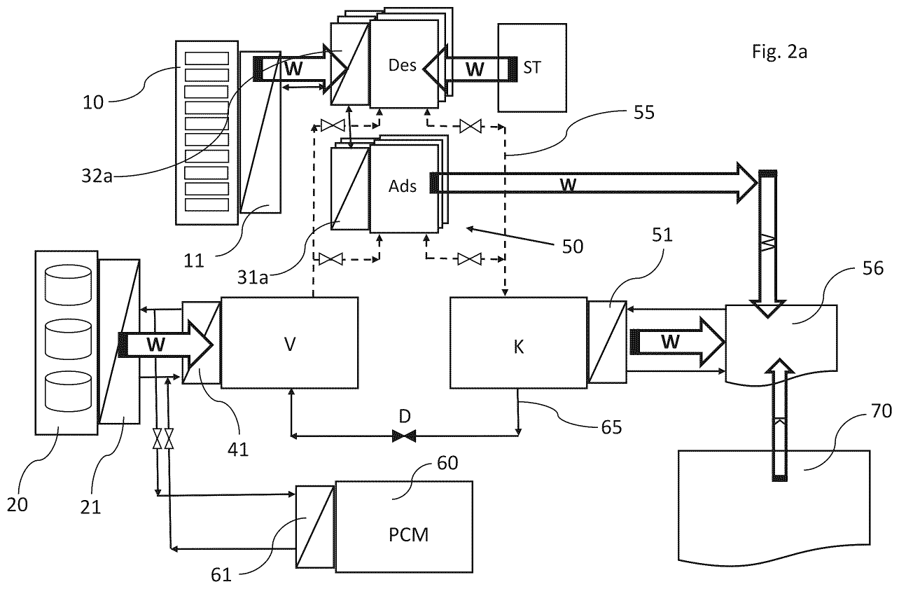

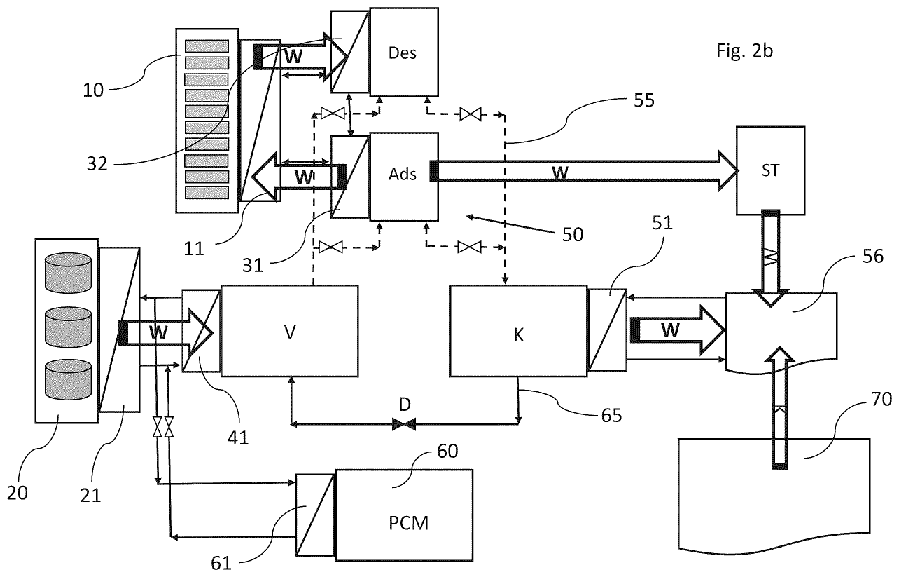

FIG. 2 shows a schematic representation of a second embodiment of a system for cooling a data center. This also has a solar thermal heating device ST, which can be coupled to the respective desorber to support the desorption process and can be used for further energy savings.

FIG. 2a shows a variant of the embodiment shown in FIG. 2. An automatic parallel and series connection within the adsorption cascade 31a, 32a enables constant return temperatures depending on the solar supply. If the temperature differences dT are large, the elements of the adsorption cascade are connected in series and if the temperature differences are small, they are connected in parallel.

FIG. 2b shows a further variant of the embodiment of FIG. 2. In this embodiment, the solar thermal heating device ST can be configured, depending on the outside temperature, to operate as a cooling source in a cooling mode, for example in winter. For this purpose, in the embodiment shown, the solar thermal heating device ST is in the cooling mode thermally coupled to the cooling reservoir 56 in order to support the re-cooling of the overall system. Alternatively or additionally, the solar heating device ST can also be thermally coupled to the adsorber Ads of the adsorption cooling device 50. The solar thermal heating system ST can thus also be used in winter to increase the efficiency of the overall system. Suitable fluids such as water, water mixed with antifreeze (glycol), alcohols or technical oils can be used as the cooling medium of the solar thermal heating device ST in cooling mode.

As a further variant, it is possible to use the solar thermal heating device ST to spatially to shade an underground cold store in order to further improve energy efficiency of the system.

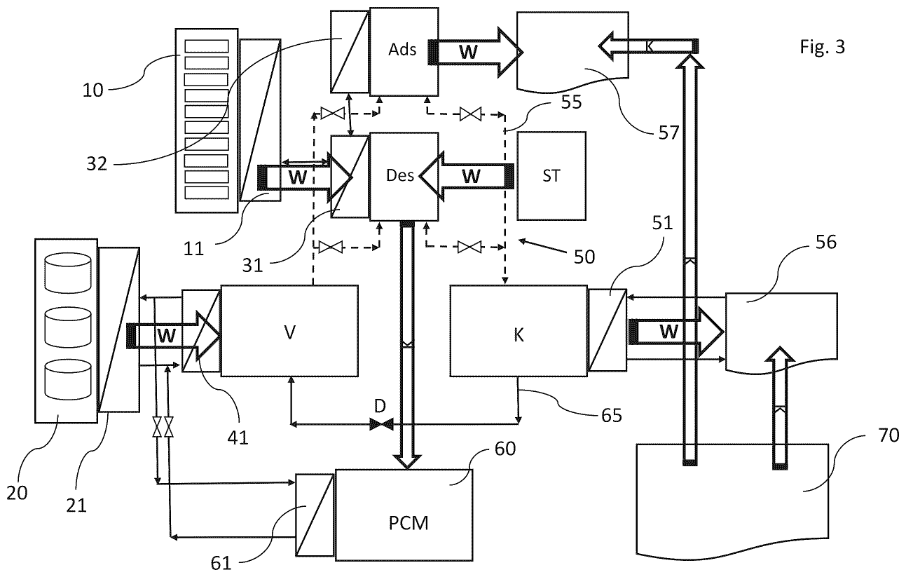

FIG. 3 shows a schematic representation of a third embodiment of a system for cooling a data center. This has a second cold storage device 70, in which the cold is stored, for example, in the concrete core of a building or in an underground cold storage system, as disclosed, for example, in DE10 2022 116 248 B1 . Alternatively, a liquid storage tank and/or a local or district cooling network can also be used for cold storage. The second cold storage device 70 is thermally coupled to the cold reservoir 56 and/or the cold reservoir 57 and can store cold for re-cooling the adsorber Ads and/or the condenser K, in particular in the cold season.

The mode of operation of the system for cooling a data center according to the present disclosure is explained below with reference to FIGS. 2 to 5.

As shown in FIG. 2, the working medium, for example water, is adsorbed on a solid adsorbent in the adsorber device Ads. As a result, the working medium in the vaporizer V changes to a gaseous state. The evaporator V absorbs heat from the functional module 20 and uses it to operate the low-temperature cooling circuit 21, 41, which is used to cool the functional module 20 of the data center. The heat flow from the functional module 20 to the evaporator V is symbolized by the arrow “W”.

In parallel, the working medium is expelled from the desorber Des by supplying external heat (arrow “W”) from the processor module 10 via the high-temperature cooling circuit 11, 31, 32 and/or from the solar thermal heater ST. The working medium then reaches the condenser K in a gaseous state and is liquefied there. The working medium releases the heat absorbed at the evaporator together with the heat supplied at the desorber Des (arrow “W”) at condenser K, which in turn is released by means of a heat exchanger 51 to a cold reservoir 56 formed, for example, by a water tank or the like. The working medium then returns to the evaporator V in liquid form via a return flow 65. This closes the working cycle of the adsorption cooling device.

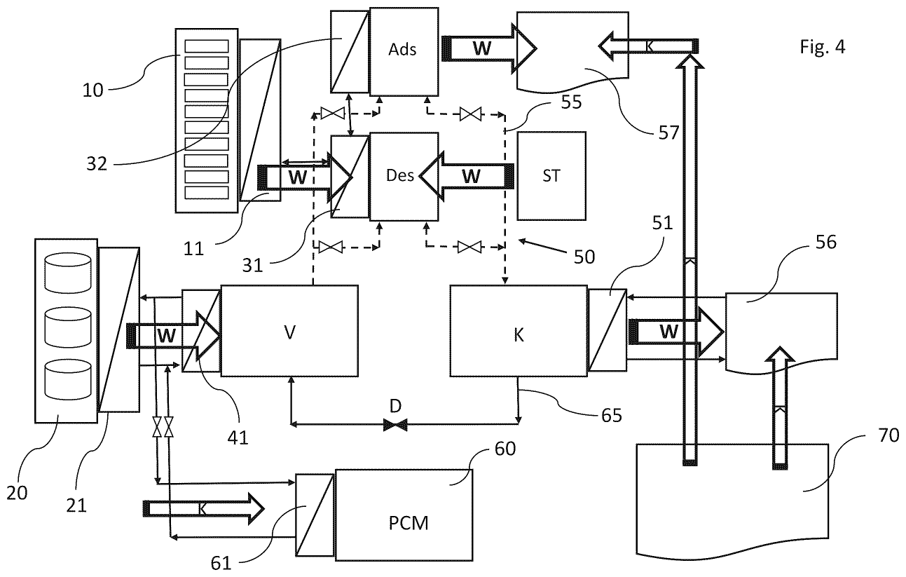

Once the adsorber Ads is saturated with the working medium, the system switches to the second part of the working cycle, which is illustrated in FIG. 4.

By opening or closing the valves, the previous adsorber Ads becomes a desorber Des and vice versa, as explained in FIG. 2. This also reverses the heat flow in the high-temperature cooling circuit 11, 31, 32, as again illustrated by the arrows “W” for heat and “K” for cool.

If, for example, the return temperature in the low-temperature cooling circuit 21, 41 falls below a certain level, for example because not the entire cooling capacity of the evaporator V is required, some of the cold generated can be stored efficiently and in a space-saving manner in the PCM cold accumulator, as schematically illustrated in FIG. 4. Conversely, if the required re-cooling capacity of the cooling reservoir 56 is not sufficient, cold can be “extracted” from the PCM cold accumulator 60 via the heat exchanger 61. This additional cooling capacity, which can be called up from the PCM cold accumulator as required, means that the performance and therefore the costs of the entire cooling system can be reduced. In addition, the output of the cooling system can also be reduced in the event of short-term increases in electricity prices and, conversely, the cold accumulator can be replenished in times of low electricity prices.

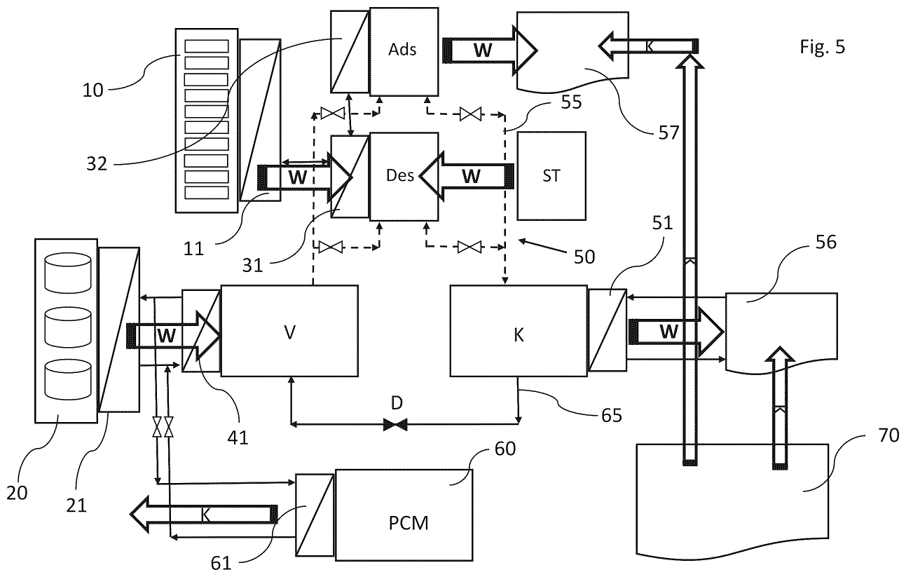

FIG. 4 schematically shows the storage of cold (arrow “K”) in the PCM cold accumulator 60 and FIG. 5 the removal of cold (arrow “K”) from the PCM cold accumulator 60 in order to support the cooling of the function module 20 and thus increase the cooling capacity of the overall system.

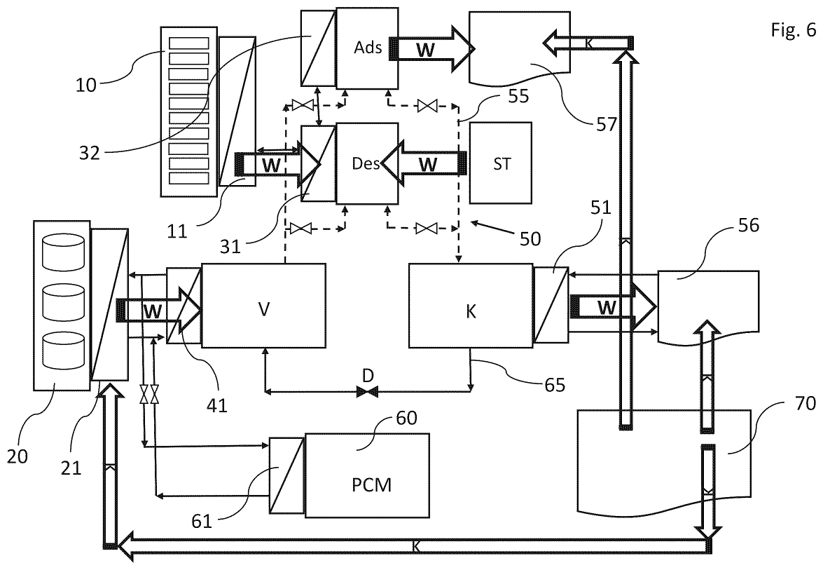

FIG. 6 shows the function of the second cold accumulator 70, which can be used in particular in “winter mode” to cool the function module 20 and/or the cold reservoirs 56 and 57. In this case, ambient cold is thermally coupled to the cold reservoirs 56 and 57 and/or directly to the heat exchanger 21 of the function module 20 by means of the building core storage device, liquid cold storage tank and/or the local or district cooling network, depending on the outside temperature. As a result, for example in winter operation, a considerable part of the cooling capacity can be provided by ambient cooling, which makes it possible to reduce the cooling energy consumption of the data center.

In summary, the system according to the present disclosure enables the efficient cooling of a data center such as an AI data center. The high-temperature waste heat from the high-performance components can be used efficiently to operate the adsorption cooling device and the efficient PCM cold storage enables a reduction in the maximum cooling capacity specification and thus the costs of the overall cooling system by buffering and recovering cooling capacity at peak load times, without jeopardizing the availability of the data center.

### LIST OF REFERENCE SYMBOLS

Ads Adsorber
Des Desorber
V Vaporizer
K Condensor
D Throttle
PCM Phase change material cold storage device
ST Solar thermal system
10 Computing module
11 Heat exchanger
20 Function module
21 Thermal interface
31 Heat exchanger
31a Adsorption cascade
32 Heat exchanger
32a Adsorption cascade
41 Thermal interface
50 Adsorption cooling device
51 Heat exchanger
55 Gas half-cycle of the adsorption cooling device
56 Cold reservoir
60 Cold storage device
61 Heat exchanger
65 Liquid half-cycle of the adsorption cooling device
70 Cold storage device

What is claimed is:

1. A system for cooling a data center comprising a plurality of computing modules with semiconductor devices, the semiconductor devices representing a heat source during operation, the system having:
a cooling device for cooling the plurality of computing modules by means of a coolant fluid circuit, the cooling device comprising an adsorption cooling device with an evaporator, a condenser, and one or more adsorption/desorption elements forming the coolant fluid circuit, the condenser having a thermal interface for delivering heat to a thermal reservoir, and
a cold storage device which is controllably thermally coupled to the adsorption cooling device for buffer storage of cold emitted by the adsorption cooling device.

2. The system according to claim 1, wherein the cold storage device comprises a phase change material (PCM) cold storage device.

3. The system according to claim 2, wherein the PCM material of the PCM cold storage device contains water, salt solutions, or kerosenes.

4. The system according to claim 1, wherein the thermal reservoir of the adsorption cooling device is thermally coupled to a second cold storage device.

5. The system according to claim 4, wherein the second cold storage device comprises an underground cold storage reservoir, a thermal building core storage device, a liquid cold storage tank, and/or a local or district cooling network.

6. The system according to claim 5, wherein the underground cold storage reservoir, the thermal building core storage device, the liquid cold storage tank and/or the local or district cooling network can be thermally coupled to the thermal reservoir and/or the adsorption cooling device as a function of the outside temperature.

7. The system according to claim 1, wherein the adsorption/desorption elements of the adsorption cooling device are controllably thermally coupled to a solar thermal heating device for thermal support of the desorption process.

8. The system according to claim 7, wherein the solar thermal heating device is configurable to operate in a cooling mode as a cooling source depending on an outside temperature.

9. The system according to claim 6, wherein the solar thermal heating device in cooling mode can be thermally coupled to the adsorption elements and/or the cooling reservoir.

10. The system according to claim 1, wherein the adsorption/desorption elements of the adsorption cooling device are thermally coupled to the plurality of computing modules of the data center, wherein the heat emitted by the plurality of computing modules is used to desorb the coolant fluid.

11. The system according to claim 10, wherein the adsorption/desorption elements of the adsorption cooling device are thermally coupled to the plurality of computing modules of the data center by means of heat exchangers via a high-temperature cooling circuit, wherein the temperature of the heat exchange medium flowing back from the plurality of computing modules to the adsorption element is at least 500 C, preferably at least 550 C, and more preferably at least 600 C.

12. The system according to claim 10, wherein at least two adsorption and desorption elements of the adsorption cooling device can be thermally coupled to the plurality of computing modules of the data center in alternating cycles for continuous cooling operation.

13. The system according to claim 1, wherein the adsorption/desorption elements of the adsorption cooling device have an adsorption cascade which can be switched between series and parallel connection depending on the temperature.

14. The system according to claim 1, wherein the evaporator of the adsorption cooling device is thermally coupled via a low-temperature cooling circuit to other functional modules of the data center, which have a lower operating temperature than the plurality of computing modules.

15. The system according to claim 14, wherein the other functional modules contain storage components and/or network components of the data center.

16. The system according to claim 1, wherein the coolant fluid of the adsorption cooling device is water.

17. The system according to claim 1, wherein the sorbent of the adsorption cooling device is zeolite or silica gel.

18. The system according to claim 1, wherein the data center is an artificial intelligence (AI) data center and the semiconductor components of the plurality of computing modules comprise graphics processing unit (GPU) or central processing unit (CPU) chips set up for AI applications.

19. A data center comprising the system according to claim 1.

20. A method for cooling a data center comprising a plurality of computing modules with semiconductor devices, the semiconductor devices representing a heat source during operation, the method comprising:
cooling the plurality of computing modules using a cooling device having an adsorption cooling device with an evaporator, a condenser, and adsorption/desorption elements forming a coolant fluid circuit containing a coolant fluid, the condenser having a thermal interface for delivering heat to a thermal reservoir;
thermally coupling a cold storage device to the adsorption cooling device for buffer storage of cold emitted by the adsorption cooling device; and
thermally coupling the adsorption/desorption elements of the adsorption cooling device to the plurality of computing modules of the data center, wherein heat emitted by the plurality of computing modules is used to desorb the coolant fluid in the coolant fluid circuit.
